(19) United States
(12) Patent Application Publication
(10) Pub. No.: US 2009/0160506 A1
(43) Pub. Date: Jun. 25, 2009

(54) POWER-ON CLEAR CIRCUIT

(76) Inventor: Kotaro Watanabe, Chiba-shi (JP)

Correspondence Address: BRINKS HOFER GILSON & LIONE, P.O. BOX 10395, CHICAGO, IL, 60610, US

(21) Appl. No.: 12/330,800

(22) Filed: Dec. 9, 2008

(30) Foreign Application Priority Data
Dec. 19, 2007 (JP) JP2007-327296

(51) Int. Cl. H03L 7/00

(52) U.S. Cl. 327/143

(57) ABSTRACT

Provided is a power-on clear circuit which normally operates. Even when a rising speed of a power supply voltage is slow, or when the power supply voltage rises from a voltage other than a ground voltage, a voltage of a node (C) is unlikely to become unstable owing to provision of a pull-down element (22) at the node (C). Thus, the power-on clear circuit normally operates, whereby a circuit connected to an output terminal of the power-on clear circuit may be normally initialized.

### RELATED APPLICATIONS

This application claims priority under 35 U.S.C. §119 to Japanese Patent Application No. JP2007-327296 filed on Dec. 19, 2007, the entire content of which is hereby incorporated by reference.

### BACKGROUND OF THE INVENTION

1. Field of the Invention

The present invention relates to a power-on clear circuit.

2. Description of the Related Art

Description is made of a conventional power-on clear circuit. FIG. 5 is a diagram illustrating the conventional power-on clear circuit.

When a power supply voltage rises, owing to coupling with a capacitor 11, a voltage of a node B approaches to the power supply voltage. Then, through an inverter 21, a voltage of a node C becomes a low signal. The voltage of the node C is subjected to waveform shaping by a waveform shaping circuit 103. This low signal initializes a circuit connected to a node D. Further, when the voltage of the node C becomes the low signal, an enhancement-type (E-type) NMOS transistor 3 as a feedback circuit is turned off, and hence the E-type NMOS transistor 3 does not function.

After that, through a control circuit 101, a voltage of a node A reaches to the power supply voltage. Then, an E-type NMOS transistor 2 is turned on, and a charge stored in a capacitor 11 is discharged via a depletion-type (D-type) NMOS transistor 1 and the E-type NMOS transistor 2, thereby causing the voltage of the node B approaches to a ground voltage. Then, through the inverter 21, the voltage of the node C becomes a high signal. The voltage of the node C is subjected to waveform shaping by the waveform shaping circuit 103, and then becomes a high signal at the node D. This high signal allows a circuit connected to the node D to normally operate. Further, when the voltage of the node C becomes the high signal, the E-type NMOS transistor 3 is turned on, and then the voltage of the node B becomes the ground voltage. In other words, the ground voltage of the node B and the high signal of the node C are held (for example, see JP 10-200053 A).

However, when a rising speed of the power supply voltage is slow or when the power supply voltage rises from a voltage other than the ground voltage, there occurs a case in which the voltage of the node C becomes unstable, which results in the power-on clear circuit not normally operating.

### SUMMARY OF THE INVENTION

The present invention has been made in view of the above-mentioned problem, and provides a power-on clear circuit which normally operates.

In order to solve the above-mentioned problem, the present invention provides a power-on clear circuit including: a capacitor having one end connected to a power supply terminal; an inverter which has an input terminal connected to another end of the capacitor and detects that a voltage of the power supply terminal reaches to a predetermined voltage; a waveform shaping circuit connected to an output terminal of the inverter; a charge/discharge circuit which discharges a voltage of the capacitor in accordance with an output of the waveform shaping circuit; and a feedback circuit which inverts a voltage of the output terminal of the inverter and then returns the inverted voltage to the input terminal of the inverter, in which a pull-down circuit is provided at a node between the output terminal of the inverter and an input terminal of the feedback circuit.

Further, the present invention provides a power-on clear circuit including: an inverter; and a capacitor which has one end provided at a power supply terminal and has another end provided at an input terminal of the inverter, the capacitor being configured to: store a charge when a power supply voltage rises, thereby causing a voltage of the another end to approach to near the power supply voltage; and discharge the stored charge when after a predetermined period of time has elapsed, thereby causing the voltage of the another end to approach to a ground voltage, in which the inverter inverts the voltage of the another end and then outputs a signal for initializing a circuit connected to an output terminal of the power-on clear circuit.

According to the present invention, even when the rising speed of the power supply voltage is slow or the power supply voltage rises from a voltage other than the ground voltage, the voltage of the output terminal of the inverter is unlikely to become unstable owing to the provision of a pull-down element at the output terminal of the inverter. Thus, the power-on clear circuit normally operates.

Further, according to the present invention, even when the rising speed of the power supply voltage is slow or the power supply voltage rises from a voltage other than the ground voltage, the voltage of the output terminal of the inverter is more likely to become a low signal due to an inversion voltage of the inverter being set smaller than a normal inversion voltage, which means that the voltage of the output terminal of the inverter is unlikely to become unstable. Thus, the power-on clear circuit normally operates.

### BRIEF DESCRIPTION OF THE DRAWINGS

In the accompanying drawings:

FIG. 1 is a diagram illustrating a power-on clear circuit according to a first embodiment of the present invention;

FIG. 2 is a diagram illustrating an example of a pull-down element of the power-on clear circuit according to the first embodiment of the present invention;

FIG. 3 is a diagram illustrating another example of the pull-down element of the power-on clear circuit according to the first embodiment of the present invention;

FIG. 4 is a diagram illustrating a power-on clear circuit according to a second embodiment of the present invention; and

FIG. 5 is a diagram illustrating a conventional power-on clear circuit.

### DETAILED DESCRIPTION OF THE PREFERRED EMBODIMENTS

Hereinbelow, embodiments of the present invention are described with reference to the drawings.

### First Embodiment

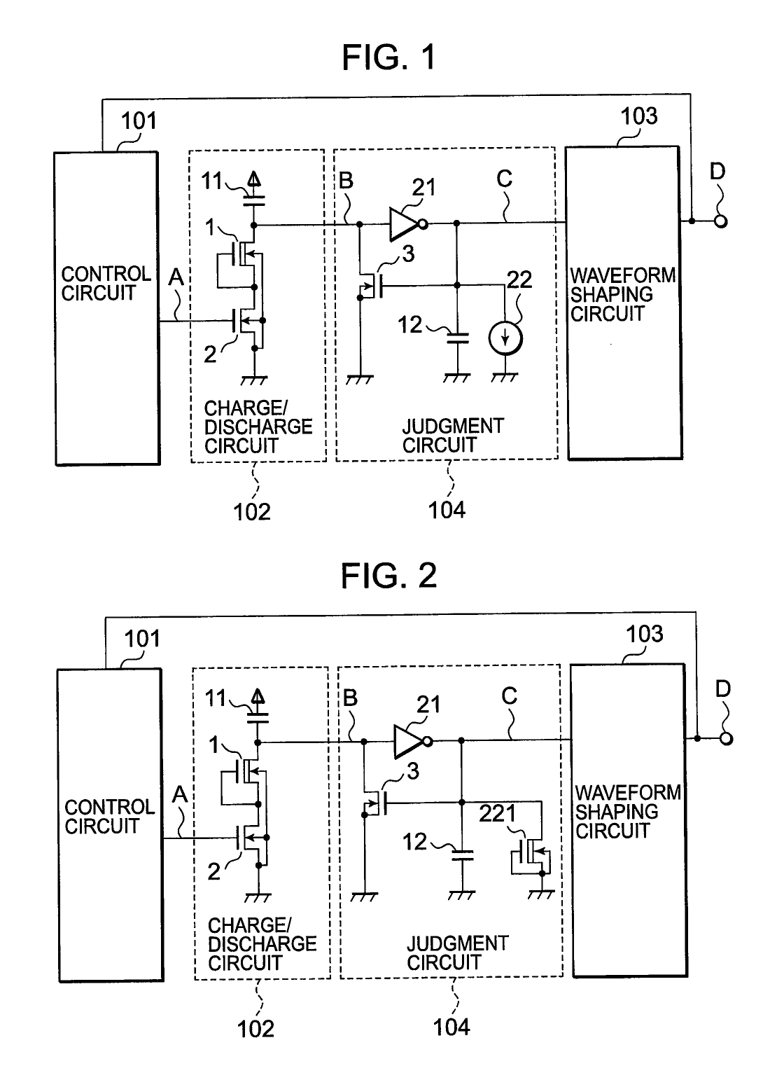

First, a configuration of a power-on clear circuit according to a first embodiment of the present invention is described. FIG. 1 is a diagram illustrating the power-on clear circuit according to the first embodiment of the present invention.

The power-on clear circuit includes a control circuit 101, a charge/discharge circuit 102, a judgment circuit 104, and a waveform shaping circuit 103. The charge/discharge circuit 102 includes a capacitor 11, a depletion-type (D-type) NMOS transistor 1, and an enhancement-type (E-type) NMOS transistor 2. The judgment circuit 104 includes an inverter 21, an E-type NMOS transistor 3, and a capacitor 12, and a pull-down element 22.

The control circuit 101 has an input terminal connected to an output terminal of the power-on clear circuit, and has an output terminal connected to a gate of the E-type NMOS transistor 2. The capacitor 11 has one end connected to a power supply terminal, and has another end connected to a drain of the D-type NMOS transistor 1. The D-type NMOS transistor 1 has a gate and a source connected to a drain of the E-type NMOS transistor 2. The E-type NMOS transistor 2 has a source connected to a ground terminal. The inverter 21 has an input terminal connected to the another end of the capacitor 11, and has an output terminal connected to an input terminal of the waveform shaping circuit 103. The E-type NMOS transistor 3 has a gate connected to an output terminal of the inverter 21, and has a source and a drain connected to the ground terminal and the input terminal of the inverter 21, respectively. The E-type NMOS transistor 3 functions as a feedback circuit of the inverter 21. The capacitor 12 is provided between the output terminal of the inverter 21 and the ground terminal. The pull-down element 22 is provided between the output terminal of the inverter 21 and the ground terminal. The waveform shaping circuit 103 has an output terminal connected to the output terminal of the power-on clear circuit.

In the control circuit 101, when a voltage at the input terminal becomes a power supply voltage, a voltage at the output terminal becomes a ground voltage. On the other hand, in the control circuit 101, when the voltage at the input terminal becomes the ground voltage, the voltage at the output terminal becomes the power supply voltage. When the power supply voltage rises, the capacitor 11 stores a charge, and a voltage of a node B approaches to near the power supply voltage. Then, after a predetermined period of time has elapsed, the capacitor 11 discharges the stored charge, and the voltage of the node B approaches to near the ground voltage. The inverter 21 inverts the voltage of the node B, and then outputs a signal for initializing a circuit connected to the output terminal of the power-on clear circuit. The pull-down element 22 pulls down an output from the output terminal of the inverter 21 while the voltage of the node B approaching to near the power supply voltage. The waveform shaping circuit 103 is, for example, a buffer or a two-phase inverter.

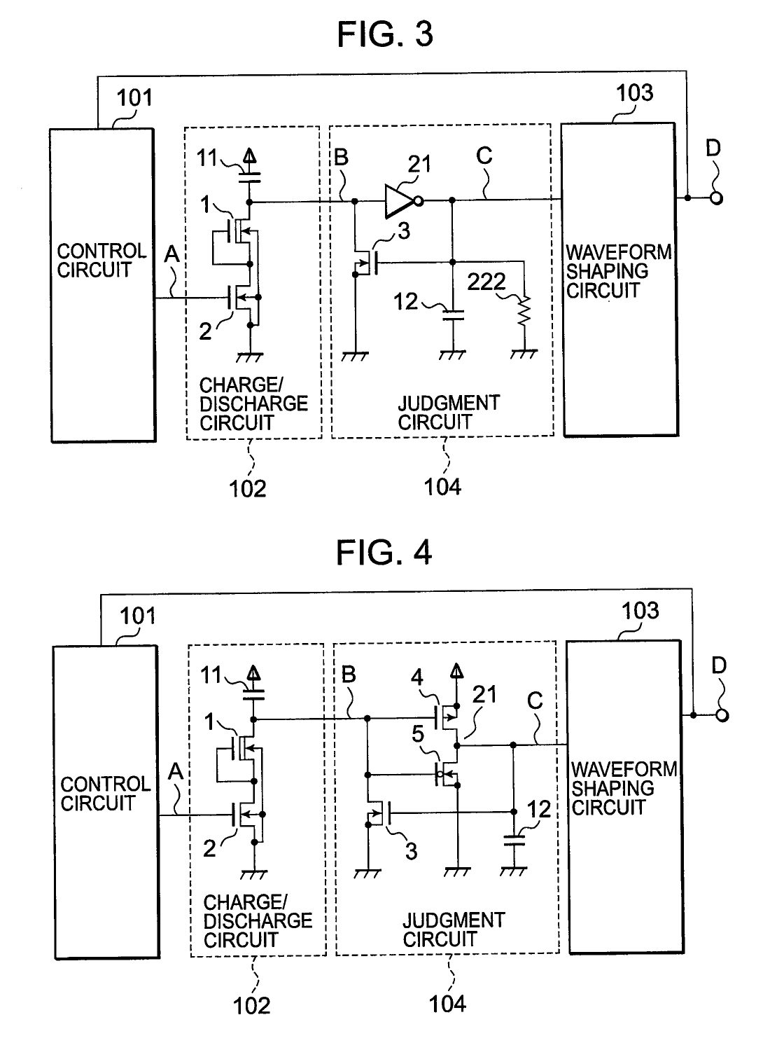

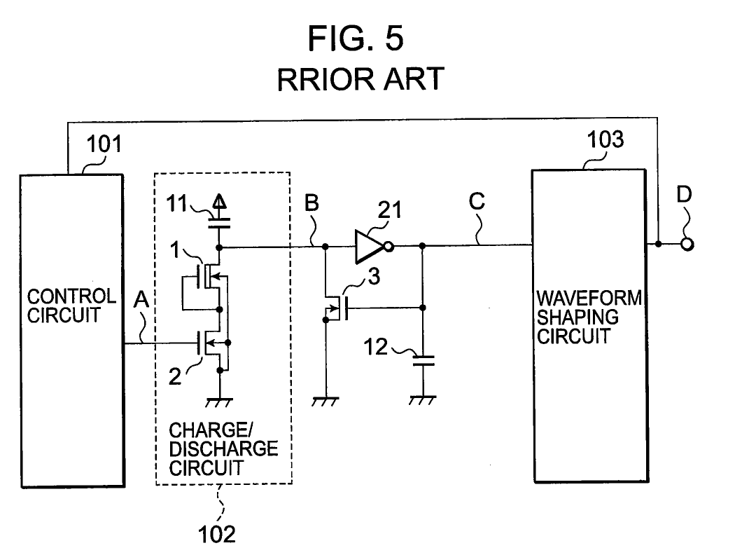

Here, the pull-down element 22 of FIG. 1 is realized by, for example, as illustrated in FIG. 2, a D-type NMOS transistor 221 which has a gate and a source connected to the ground terminal and has a drain connected to the output terminal of the inverter 21. The D-type NMOS transistor 221 functions as a constant current source. Further, the pull-down element 22 of FIG. 1 is realized by, for example, as illustrated in FIG. 3, a resistor 222 which has one end connected to the output terminal of the inverter 21 and has another end connected to the ground terminal. The resistor 222 functions as a pull-down resistor.

Next, operation of the power-on clear circuit is described.

When the power supply voltage rises, owing to coupling with the capacitor 11, the voltage of the node B approaches to the power supply voltage. Then, through the inverter 21, a voltage of a node C becomes a low signal. Further, through the pull-down element 22 provided at the node C, the voltage of the node C also becomes a low signal. In other words, the voltage of the node C is unlikely to become unstable. The voltage of the node C is subjected to waveform shaping by the waveform shaping circuit 103, and then becomes a low signal at a node D. This low signal initializes a circuit connected to the node D. Further, when the voltage of the node C becomes a low signal, the E-type NMOS transistor 3 is turned off and the E-type NMOS transistor 3 does not function.

After that, through the control circuit 101, a voltage of a node A becomes the power supply voltage. Then, the E-type NMOS transistor 2 is turned on, and the charge stored in the capacitor 11 is discharged via the D-type NMOS transistor 1 and the E-type NMOS transistor 2, whereby the voltage of the node B approaches to the ground voltage. Then, through the inverter 21, the voltage of the node C becomes a high signal. Here, even if the pull-down element 22 is provided at the node C, the voltage of the node C can become a high signal when the voltage of the node B becomes the ground voltage, owing to the fact that a PMOS transistor (not shown) of the inverter 21 has a higher driving capability than the pull-down element 22 provided at the node C. The voltage of the node C is subjected to waveform shaping by the waveform shaping circuit 103, and then becomes a high signal at the node D. This high signal causes the circuit connected to the node D to normally operate. Further, when the voltage of the node C becomes a high signal, the E-type NMOS transistor 3 is turned on, and then the voltage of the node B becomes the ground voltage. In other words, the ground voltage of the node B and the high signal of the node C are held.

With this, even when the rising speed of the power supply voltage is slow or the power supply voltage rises from a voltage other than the ground voltage, the voltage of the node C is unlikely to become unstable owing to the provision of the pull-down element 22 at the node C. Thus, the power-on clear circuit normally operates, whereby the circuit connected to the output terminal of the power-on clear circuit may be normally initialized.

### Second Embodiment

Next, a configuration of a power-on clear circuit according to a second embodiment of the present invention is described. FIG. 4 is a diagram illustrating the power-on clear circuit according to the second embodiment of the present invention.

In the power-on clear circuit according to the second embodiment of the present invention, compared to the power-on clear circuit according to the first embodiment of the present invention, the pull-down element 22 is eliminated. In addition, the E-type NMOS transistor of the inverter 21 is replaced with an E-type NMOS transistor 5 which has a lower threshold voltage than a usual E-type NMOS transistor. In other words, an input voltage which is inverted by the inverter 21 upon outputting may be made lower than the input voltage of a usual inverter.

Next, operation of the power-on clear circuit is described.

When the power supply voltage rises, due to coupling with the capacitor 11, the voltage of the node B approaches to the power supply voltage. Then, through the inverter 21, the voltage of the node C becomes a low signal. Here, the inversion voltage of the inverter 21 is set smaller than a normal inversion voltage, and hence the voltage of the node C becomes the low signal not only when the voltage of the node B becomes equal to or larger than the normal inversion voltage but also when the voltage of the node B is smaller than the normal inversion voltage and equal to or larger than the inversion voltage of the inverter 21. In other words, the voltage of the node C is unlikely to become unstable. The voltage of the node C is subjected to waveform shaping by the waveform shaping circuit 103, and then becomes a low signal at the node D. This low signal initializes a circuit connected to the node D.

After that, through the control circuit 101, the voltage of the node A becomes the power supply voltage. Then, the E-type NMOS transistor 2 is turned on, and the charge stored in the capacitor 11 is discharged via the D-type NMOS transistor 1 and the E-type NMOS transistor 2, whereby the voltage of the node B approaches to the ground voltage. Then, through the inverter 21, the voltage of the node C becomes a high signal. The voltage of the node C is subjected to waveform shaping by the waveform shaping circuit 103, and then becomes a high signal at the node D. This high signal causes the circuit connected to the node D to normally operate.

With this, even when the rising speed of the power supply voltage is slow or the power supply voltage rises from a voltage other than the ground voltage, the voltage of the node C is more likely to become a low signal owing to the inversion voltage of the inverter 21 being set smaller than the normal inversion voltage, which means that the voltage of the node C is unlikely to become unstable. Thus, the power-on clear circuit normally operates, whereby the circuit connected to the output terminal of the power-on clear circuit may be normally initialized.

It should be noted that the low signal which is output from the waveform shaping circuit 103 initializes the circuit connected to the node D, but may also initialize an IC connected to the node D.

What is claimed is:

1. A power-on clear circuit for detecting that a voltage of a power supply terminal reaches to a predetermined voltage to output a reset signal, comprising:
a charge/discharge circuit which is charged with the voltage of the power supply terminal and is discharged in accordance with the reset signal;
an inverter connected to an output terminal of the charge/discharge circuit;
a waveform shaping circuit which is connected to an output terminal of the inverter and outputs the reset signal;
a feedback circuit connected between the output terminal of the inverter and an input terminal of the inverter; and
a pull-down circuit provided at a node between the output terminal of the inverter and an input terminal of the feedback circuit.

2. A power-on clear circuit according to claim 1, wherein the pull-down circuit comprises a constant current circuit.

3. A power-on clear circuit according to claim 1, wherein the pull-down circuit comprises a resistor.

4. A power-on clear circuit for detecting that a voltage of a power supply terminal reaches to a predetermined voltage to output a reset signal, comprising:
a charge/discharge circuit which is charged with the voltage of the power supply terminal and is discharged in accordance with the reset signal;
an inverter connected to an output terminal of the charge/discharge circuit;
a waveform shaping circuit which is connected to an output terminal of the inverter and outputs the reset signal; and
a feedback circuit connected between the output terminal of the inverter and an input terminal of the inverter,
wherein an NMOS transistor of the inverter has a lower threshold voltage than a usual threshold voltage.
